(19) United States
(12) Patent Application Publication
(10) Pub. No.: US 2021/0214864 A1
(43) Pub. Date: Jul. 15, 2021

(54) Optoelectronic Fiber as well as Apparatus and Method for Manufacturing an Optoelectronic Fiber

(71) Applicant: OSRAM OLED GmbH, Regensburg (DE)

(72) Inventors: Michael Bestele, Lappersdorf (DE); Siegfried Herrmann, Neukirchen (DE)

(21) Appl. No.: 17/252,213

(22) PCT Filed: May 24, 2019
(86) PCT No.: PCT/EP2019/063528

§ 371 Date: Dec. 14, 2020

(30) Foreign Application Priority Data
Jun. 15, 2018 (DE) 10 2018 114 465.2

(51) Int. Cl. D02G 3/44; F21S 4/26; D03D 1/00

(52) U.S. Cl. CPC D02G 3/441; F21S 4/26; F21Y 2115/10; D10B 2401/18; D03D 1/0088

(57) ABSTRACT

An optoelectronic fiber, an apparatus for manufacturing an optoelectronic fiber and a method for manufacturing an optoelectronic fiber are disclosed. In an embodiment an optoelectronic fiber includes at least one carrier extending in a longitudinal direction, optoelectronic components arranged on the at least one carrier and a sheath extending in the longitudinal direction and surrounding the at least one carrier and the optoelectronic components, wherein the sheath includes at least one thread guided around the at least one carrier and the optoelectronic components and/or at least one tape helically wound around the at least one carrier and the optoelectronic components, wherein at least one metal wire is integrated into the sheath and twisted, braided or interwoven with the at least one thread, and wherein the at least one metal wire is electrically coupled to at least one of the optoelectronic components.

This patent application is a national phase filing under section 371 of PCT/EP2019/063528, filed May 24, 2019, which claims the priority of German patent application 10 2018 114 465.2, filed Jun. 15, 2018, each of which is incorporated herein by reference in its entirety.

### TECHNICAL FIELD

The present invention relates to an optoelectronic fiber, in particular for integration into a textile or a molded part, as well as an apparatus and a method for manufacturing an optoelectronic fiber.

### BACKGROUND

More and more luminous textiles, especially garments, are coming onto the market. There is also an interest in molded parts with luminous sections.

### SUMMARY

Embodiments provide an optoelectronic fiber which can be produced easily, quickly and/or cheaply and which can be used particularly easily in connection with textiles or molded parts. Further embodiments provide a device and a method with which such an optoelectronic fiber can be produced in a simple, fast and/or inexpensive manner.

An optoelectronic fiber according to a first embodiment, which is particularly suitable or intended for integration into a textile or a molded part, comprises at least one carrier extending in a longitudinal direction, and optoelectronic components arranged on the carrier. A sheath or cover extending in the longitudinal direction surrounds the at least one carrier and the optoelectronic components. The sheath comprises at least one thread or filament, i.e. one or more threads or filaments, and/or at least one tape or band, i.e. one or more tapes or bands, helically or spirally wound around the at least one carrier and the optoelectronic components.

In particular, the optoelectronic fiber may be designed and dimensioned in such a way that it can be integrated into a textile, comparable to a textile thread, in particular by using the usual weaving and/or knitting and/or embroidery techniques. In addition, the optoelectronic fiber is flexible and can therefore be easily wound up and provided on a bobbin or coil like a conventional thread.

By integrating such thread-like lighting devices, illuminated textiles can be realized. The use of such textiles in articles of clothing can, for example, help to increase the safety of pedestrians or cyclists who are on the road in poor visibility conditions or in the dark.

The sheath can in particular be dimensioned and embodied in such a way that the thread-like fiber formed behaves at least approximately like a textile thread and in particular forms a flexural limp structure which—viewed in the longitudinal direction—has at least substantially a dominant one-dimensional extension and/or a uniform cross-section. The cross section can in particular be circular. Other cross-sectional shapes, such as oval, rectangular or square, are also possible. The carrier and the optoelectronic components arranged on the carrier can also be dimensioned in the same way. In particular, the carrier can be embodied in such a way that, as a component of the fiber, it behaves flexurally slack and thus does not break or tear when incorporated into a textile fabric with normal textile threads. The optoelectronic fiber can be incorporated into textiles before the sheathing material hardens. The subsequent curing of the sheath causes the optoelectronic fiber to cross-link with the textiles.

Textiles with the optoelectronic fiber can be used in clothing, vehicle interiors, furniture, carpets or other suitable environments.

An optoelectronic component can be an electromagnetic radiation emitting component or an electromagnetic radiation absorbing component. An electromagnetic radiation absorbing component can be a solar cell, for example. An electromagnetic radiation-emitting component can be an electromagnetic radiation-emitting semiconductor component in various embodiments and/or be designed as an electromagnetic radiation-emitting diode, an organic electromagnetic radiation-emitting diode, an electromagnetic radiation-emitting transistor or an organic electromagnetic radiation-emitting transistor. The radiation can be for example light in the visible range, UV light and/or infrared light. In this context, the electromagnetic radiation emitting component can be designed as a light emitting diode (LED), an organic light emitting diode (OLED), a light emitting transistor or an organic light emitting transistor. The light emitting component can be part of an integrated circuit in various forms. Furthermore, a plurality of light emitting components can be provided, for example, housed in a common package.

Since the sheath should completely surround both the carrier and the optoelectronic components, the optoelectronic components are also correspondingly small. For example, LED chips with a conventional height of 100 to 300 μm can be used, but the LED chips can also have a lower height, for example in the range of 5 to 20 μm or even lower.

Furthermore, the optoelectronic fiber can be integrated into a molded part, for example a car body part, such as an engine hood. This enables the illumination of the molded part at a desired location.

In addition to the optoelectronic components, other components can also be arranged on the carrier, such as electronic components, switching elements, piezoelectric elements, miniature generators and/or micro-electro-mechanical systems (MEMS).

The optoelectronic fiber comprises one or more carriers, on each of which one or more optoelectronic components are arranged.

The at least one thread and/or the at least one tape may be pre-produced and, for example, wound on spools from which they are unwound during the manufacture of the optoelectronic fiber. However, the at least one thread and/or the at least one tape may also be produced during the manufacture of the optoelectronic fiber by means of an extrusion process. In this way, the at least one thread and/or the at least one tape can be produced particularly easily and in particular also as “endless threads” or “endless tape”.

By coating the strand formed by the at least one carrier and the optoelectronic components arranged on it, unevenness in the strand can be compensated. The thickness of the coating can be kept essentially constant over the entire strand. Furthermore, a centering of the strand like in concentric extrusion, where the strand has to be centered in the middle of the extrusion die, is not necessary. Furthermore, the tensile strength of the sheathing described here is higher than that of conventionally sheathed strands.

In order to form a stable sheath around the at least one carrier and the optoelectronic components, the threads can be twisted, interlaced, interwoven or connected by other textile production techniques. Furthermore, techniques from the cable manufacturing industry can also be used to produce the sheath, for example to manufacture coaxial cables, network cables, etc. In twisting, the threads are wound helically around the at least one carrier and the optoelectronic components. For braiding and weaving, the threads are regularly intertwined, whereby the threads cross at right angles during weaving and not at right angles during braiding.

Furthermore, after the threads have been passed around the at least one carrier and the optoelectronic components, they can be cross-linked to unite the threads into one body. For this purpose, the threads can be melted, for example, or the threads can be made of a material that solidifies after the formation of the sheath, thereby forming a network of the threads. In the same way, the tape loops of the at least one tape, which are formed by helically wrapping the at least one carrier and the optoelectronic components, can be cross-linked together.

The at least one thread can be pulled through an adhesive before the sheathing is produced, in order to subsequently adhere to the at least one carrier and the optoelectronic components. In addition, the sheath can be impregnated with plastic after its manufacture. An adhesive or plastic can also be added during the manufacture of the sheath.

A flexible printed circuit board can be used as a carrier for the optoelectronic components, on which the optoelectronic components are electrically contacted and subsequently encapsulated. Alternatively, instead of the printed circuit board, an extruded plastic carrier can be used as a carrier for the optoelectronic components, in which the optoelectronic components are embedded or embossed, for example by means of a hot embossing technique.

The carrier(s) can be linear or wound or twisted. After the production of the optoelectronic fiber the coiled carriers can relax and take their original shape. Alternatively, the carriers can be left in the coiled form, which can have advantages in the radiation characteristics.

At least one thin metal wire can be integrated into the sheath, in particular several thin metal wires. The metal wire(s) may be twisted, braided, interwoven or otherwise suitably connected with the at least one thread. The sheath can be stabilized by the at least one metal wire.

Furthermore, the at least one metal wire can be used to establish an electrical contact to at least one of the optoelectronic components. One or more optoelectronic components can be electrically connected to one or more other optoelectronic components of the optoelectronic fiber. In addition, one or more optoelectronic components of the optoelectronic fiber may be electrically connected to a component outside the optoelectronic fiber via the metal wire(s). Furthermore, one or more further components, e.g. electronic and/or micromechanical components, may be integrated into the optoelectronic fiber, which may serve to control and/or supplement the functions of the optoelectronic components and which may also be contacted by the at least one metal wire.

The at least one thread and/or the at least one tape are preferably made of an electrically non-conductive material. The individual threads have a diameter that is significantly smaller than the diameter of the optoelectronic fiber. The threads can also be called fibers.

The at least one thread and/or the at least one tape may be made of a material such that the optoelectronic fiber can be integrated into a textile in the manner of a thread. The material can be, for example, silicone, which can also be mixed with an additive, for example a fluorescent substance. The material can also be transparent clear or diffuse. Threads of different materials can also be contained in one and the same sheath.

The at least one thread and/or the at least one tape may, for example, comprise plastic or may be made of plastic. The at least one thread and/or the at least one tape may for example comprise polymethyl methacrylate (PMMA), polycarbonate (PC), polyethersulfone (PES), polyethylene terephthalate (PET), polyamide (PA), polyimide (PI), polyamideimide (PAI), polyphenylene sulfide (PPS), polyacrylonitrile (PAN), polytetrafluoroethylene (PTFE), polyethylene (PE), polypropylene (PP), polyvinyl chloride (PVC), polyurethane, silicone, siloxane and/or a glass fiber material or formed from these. The at least one thread and/or the at least one tape may optionally contain heterogeneous plastic compounds. For example, they may be composed of a carbon matrix with silicone or of a metal wire matrix, or they may contain scattering particles and/or conversion material for converting the light emitted by the optoelectronic components. The concentric sheathing of the carrier—similar to a coaxial cable—and the optoelectronic components arranged on it also allows concentric refractive index curves to be generated.

The surface finish of the sheath may depend on the particular use of the optoelectronic fiber, for example, in the case of use in a textile, on the type of fabric of the textile.

Furthermore, advantageous decoupling structures can be created to lead out electrical and/or optical signals from the optoelectronic fiber.

An optoelectronic fiber according to a second embodiment, which is in particular suitable or intended for integration into a textile or a molded part, comprises at least one carrier extending in a longitudinal direction, optoelectronic components arranged on the at least one carrier, and a sheath extending in the longitudinal direction and surrounding the at least one carrier and the optoelectronic components. The sheath is a tube or hose in whose wall at least one electrical line, in particular two or more electrical lines, are integrated.

The tube or hose can be made of silicone, for example. However, other materials may also be used to make the hose, especially those materials listed above for the production of at least one thread and at least one tape.

If several electrical lines are provided in the hose, they can run parallel to each other or collinear.

The hose can be produced by an extrusion process. The electrical lines or leads can be centered by means of appropriate nozzles arranged next to the extrusion die.

The at least one substrate and the optoelectronic components may be designed in the same way as for the optoelectronic fiber according to the first embodiment.

The at least one electrical line can be electrically coupled with at least one of the optoelectronic components. This makes it possible to interconnect the optoelectronic components with each other or with a component outside the optoelectronic fiber.

A textile according to an embodiment comprises a plurality of textile threads and at least one of the optoelectronic fibers described above. The optoelectronic fibers may be integrated into the textile by one of the usual weaving and/or knitting and/or embroidery techniques. In particular, the textile may be a garment or a piece of furniture or a component part of a piece of furniture, such as part of a piece of furniture or a carpet, or a component part of a vehicle interior, such as a seat cover.

A molded part according to an embodiment comprises at least one of the optoelectronic fibers described above. The moulded part may in particular be a vehicle part, such as a body part, a hood or a headlamp. The optoelectronic fiber may be placed in a recess provided for this purpose in the moulding. If the molded part is an injection molded part, the optoelectronic fiber can be overmolded and thus, in particular, be completely surrounded by the molded part.

A device according to an embodiment comprises an assembly of any kind and at least one of the above-described optoelectronic fibers which is firmly attached to the assembly. The at least one optoelectronic fiber may be incorporated in the assembly in a desired manner such that the assembly and the at least one optoelectronic fiber form a unit. For example, the at least one optoelectronic fiber may be completely fused in a thermoplastic housing.

An apparatus according to an embodiment is used to manufacture an optoelectronic fiber as described above. The apparatus comprises a feeding device for feeding at least one carrier which extends in a longitudinal direction and on which optoelectronic components are arranged, and a wrapping device adapted to surround the at least one carrier and the optoelectronic components with a longitudinally extending sheath, in that the wrapping device guides at least one thread around the at least one carrier and the optoelectronic components and/or winds at least one tape helically around the at least one carrier and the optoelectronic components.

The wrapping device may comprise a cross-linking device. The cross-linking device is designed in such a way that it cross-links several threads and/or the tape loops with each other during and/or after they are or have been wound around the at least one carrier and the optoelectronic components. The cross-linking device can, for example, heat the threads and/or the tape in order to cross-link the threads and/or the tape loops with each other by melting or solidification.

Preferably, the wrapping device features a rotatably mounted twisting device with a first recess and several second recesses. The feeding device is designed in such a way that it guides the at least one carrier with the optoelectronic components arranged on it through the first recess coming from a first side of the twisting device. Coming from the first side of the twisting device, the threads are guided through one of the second recesses each time. Furthermore, the twisting device is rotated, which causes the threads to be guided around the at least one carrier and the optoelectronic components on the second side of the twisting device facing away from the first side and twisted. During the rotation of the twisting device, the at least one carrier with the optoelectronic components arranged thereon is guided away from the twisting device.

The first recess, through which the at least one carrier with the optoelectronic components arranged on it is guided, is preferably arranged in the axis of rotation of the twisting device.

The device can have one or more bobbins from which the thread(s) are unwound.

A method according to an embodiment is used to manufacture an optoelectronic fiber as described above. The method comprises providing at least one carrier extending in a longitudinal direction, placing optoelectronic components on the carrier, and surrounding the at least one carrier and the optoelectronic components with a sheath extending in the longitudinal direction. To produce the sheath, at least one thread is passed around the at least one carrier and the optoelectronic components. Alternatively or additionally at least one thread can be wound helically around the at least one carrier and the optoelectronic components.

If the sheath has several threads, they can be twisted, interlaced or woven together. Furthermore, the threads guided around the at least one carrier and the optoelectronic components and/or the tape loops formed by helically winding the at least one tape around the at least one carrier and the optoelectronic components can be crosslinked with each other.

At least one metal wire can be integrated into the sheath and in particular twisted, braided or interwoven with the at least one thread.

The at least one metal wire can be electrically coupled with at least one of the optoelectronic components.

Furthermore, an extruded plastic carrier can be produced to form the carrier and the optoelectronic components can be embedded in the extruded plastic carrier. The sheath can be produced by means of a rotatably mounted twisting device with a first recess and several second recesses. The at least one carrier with the optoelectronic components arranged on it is guided through the first recess coming from a first side of the twisting device and the threads are each guided through one of the second recesses coming from the first side of the twisting device. The twisting device is rotated in such a way that the threads on a second side of the twisting device facing away from the first side are guided around the at least one carrier and the optoelectronic components and the threads are thereby twisted together.

### BRIEF DESCRIPTION OF THE DRAWINGS

In the following, examples of the invention are explained in detail with reference to the attached drawings.

FIG. 1A shows a sectional view of an example of an optoelectronic fiber;

FIG. 2A shows a perspective view of an example of an apparatus and a method for manufacturing an optoelectronic fiber;

FIGS. 3A to 3C show a perspective view of an example of a method for manufacturing an optoelectronic fiber;

FIG. 4 shows a perspective view of an example of a method for manufacturing an optoelectronic fiber;

FIG. 5A shows a perspective view of an example of a method for manufacturing an optoelectronic fiber;

FIGS. 6A and 6B show perspective representations of examples of an optoelectronic fiber; and

FIGS. 7A and 7B show a perspective view and a sectional view of an example of an optoelectronic fiber.

In the following detailed description, reference is made to the attached drawings, which form part of this description and in which, for illustration purposes, specific examples of embodiments are shown in which the invention can be exercised. Since components of examples can be positioned in a number of different orientations, the terminology of directions is for illustration purposes only and is in no way restrictive. It is understood that other embodiments can be used and structural or logical changes can be made without deviating from the scope of protection. It is understood that the features of the different embodiments described herein may be combined with each other, unless specifically stated otherwise. The following detailed description is therefore not to be understood in a restrictive sense. In the figures, identical or similar elements are marked with identical reference signs, where appropriate.

### DETAILED DESCRIPTION OF ILLUSTRATIVE EMBODIMENTS

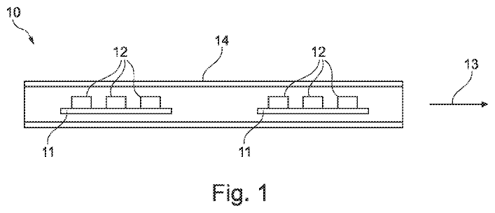

FIG. 1 shows a sectional view of an example of an optoelectronic fiber 10, which is particularly suitable or intended for integration into a textile or molded part.

The optoelectronic fiber 10 comprises several carriers 11, on each of which several optoelectronic components 12 are arranged. FIG. 1 shows an example of two carriers 11 with three components 12 arranged on each carrier 11. However, the optoelectronic fiber 10 can also contain exactly one or more than two carriers 11. Furthermore, each of the carriers 11 can hold a desired number of optoelectronic components 12.

The carriers 11 extend in a longitudinal direction, which is shown in FIG. 1 by an arrow 13. In the longitudinal direction there is also a sheath 14 which surrounds the carriers 11 and the optoelectronic components 12. The sheath 14 may be formed either by one or more threads wound around the carriers 11 and the optoelectronic components 12 or by one or more tapes helically wound around the carriers 11 and the optoelectronic components 12. Furthermore, the sheath 14 can also consist of a braid of individual threads and a helically wound tape. The thread or threads and the tape or tapes are made of a plastic material in particular.

The optoelectronic components 12 can be designed in particular as LED chips. In addition to the optoelectronic components 12, other components can also be placed on the carriers 11.

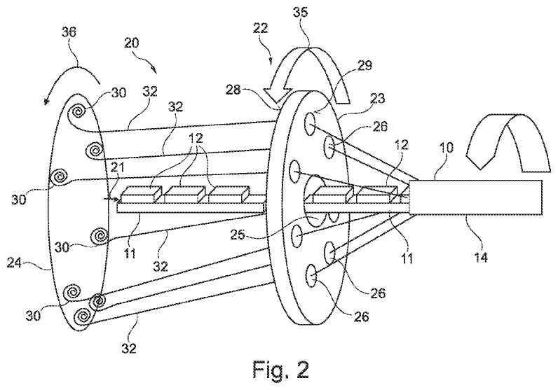

FIG. 2 shows a perspective view of an example of an apparatus 20 and a method for manufacturing an optoelectronic fiber 10.

The apparatus 20 contains a feeding device not shown in FIG. 2, which serves to feed carriers 11 with optoelectronic components 12 arranged on them. The carriers 11 are fed to a wrapping device 22 along a direction indicated by an arrow 21 in FIG. 2. The feeding device may, for example, have a conveyor belt for feeding the carriers 11.

The wrapping device 22 has a rotatably mounted twisting device 23 and a likewise rotatably mounted unwinding device 24.

The twisting device 23 can essentially have the shape of a disc with an essentially circular circumference.

A first recess 25 is located in the axis of rotation of the twisting device 23, and several second recesses 26 are arranged along the circumference of the twisting device 23. The first and second recesses 25, 26 each extend from a first side 28 of the twisting device 23 to a second side 29 of the twisting device 23 opposite the first side 28.

The unwinding device 24 can essentially have the shape of a disc with an essentially circular circumference. Several bobbins 30 are arranged along the circumference of the unwinding device 24, onto which a respective thread 32 is wound.

The feeding device feeds the carriers 11 with the optoelectronic components 12 arranged on them to the twisting device 23 in such a way that the carriers 11 are fed from the first side 28 through the first recess 25 in the twisting device 23. Furthermore, each of the threads 32 is passed through one of the second recesses 26 from the first side 28.

On the second side 29 of the twisting device 23, the several individual threads 32 are passed around the carriers 11 and the optoelectronic components 12 and twisted together to form the sheath 14 of the optoelectronic fiber 10. During the twisting process, the threads 32 are unwound from the bobbins 30. The carriers 11 with the optoelectronic components 12 can, for example, be guided away from the twisting device 23 by means of a conveyor belt.

To twist the threads 32, the twisting device 23 is rotated about its axis of rotation in a direction indicated by the arrow 35 in FIG. 2. In the same way, the unwinding device 24 is rotated in a direction of arrow 36.

Furthermore, one or more metal wires can be inserted into the sheath 14 by unwinding them from bobbins 30 in the same way as the threads 32, passing them through corresponding second recesses 26 in the twisting device 23 and twisting them with the threads 32.

After twisting the threads 32, they can be cross-linked with each other. For this purpose, the threads 32 can be melted, for example, or the threads 32 can be made of a material that solidifies after forming the sheath 14, thereby forming a cross-linking of the threads 32.

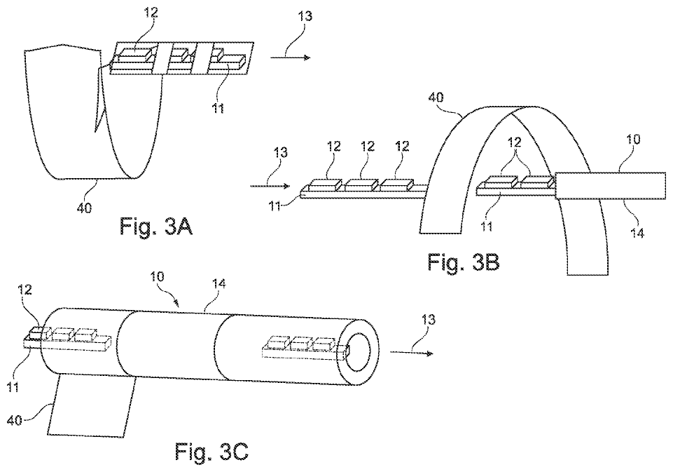

FIGS. 3A to 3C show perspective views of a process for the manufacture of an optoelectronic fiber 10.

Carriers 13 are provided, which extend in the longitudinal direction represented by the arrow 13. The optoelectronic components 12 are arranged on the carriers 11. Subsequently, the carriers 11 and the components 12 arranged on them are wrapped helically along the longitudinal direction with a tape 40, thus producing the sheath 14. FIGS. 3A to 3C show different phases of the production of the sheath 14.

The tape loops created by wrapping tape 40 around the carrier 11 and the optoelectronic components 12 can be cross-linked with each other, for example by melting or solidifying.

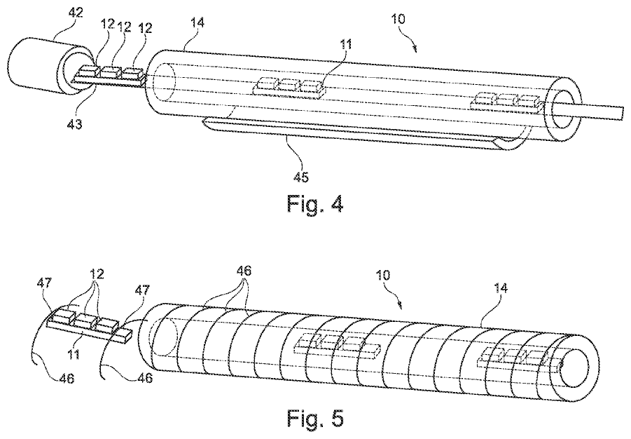

FIG. 4 shows a perspective view of an example of a method for manufacturing an optoelectronic fiber 10.

In this example, an extrusion die 42 produces a plastic strand 43 from which the carriers 11 are produced by cutting the plastic strand 43 at suitable points. The optoelectronic components 12 are embedded or stamped into the plastic strand 43, for example by means of a hot embossing technique. Then the carriers 11 and the optoelectronic components 12 are surrounded by the sheath 14.

Furthermore, in FIG. 4 a band reflector 45 is linearly laminated onto the sheath 14.

FIG. 5 shows a perspective view of an example of a method for the manufacture of an optoelectronic fiber 10. The example shown in FIG. 5 is a further development of the example shown in FIG. 2, in which metal wires 46 are inserted into the sheath 14 of the optoelectronic fiber 10 in addition to the plastic threads 32.

Before the sheath 14 is manufactured, the metal wires 46 are wound at connection points 47 of the carrier 11, pressed there and then contacted by means of a suitable process, for example friction welding. In this case, the carrier 11 is a flexible printed circuit board through which the optoelectronic components 12 are electrically coupled to the metal wires 46.

The metal wires 46 make it possible to electrically connect the optoelectronic components 12 to each other and/or to a component outside the optoelectronic fiber 10.

Furthermore, the metal wires 46 stabilize the sheath 14 and mechanically support an extrusion process for the production of the carriers 11. The plastic strand 43 is pulled evenly from the extrusion die 42 and can break off without reinforcement.

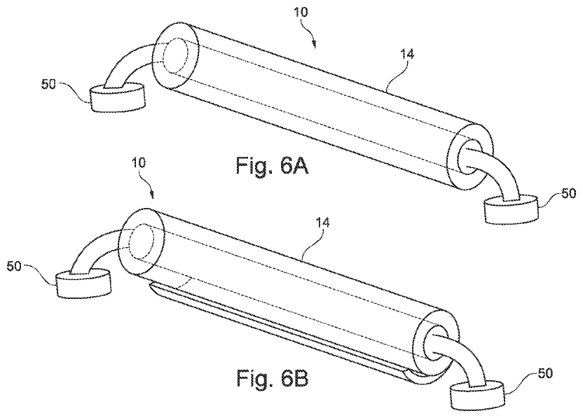

FIGS. 6A and 6B show perspective views of examples of an optoelectronic fiber 10.

At the ends of the optoelectronic fibers 10, respective connecting contacts 50 are led out of the optoelectronic fibers 10, via which the optoelectronic fibers 10 can be contacted externally. The shown optoelectronic fibers 10 can be integrated into textiles or molded parts. Further applications are conceivable. For example, the optoelectronic fibers 10 can be installed in the floor of an airplane to mark an escape route for passengers.

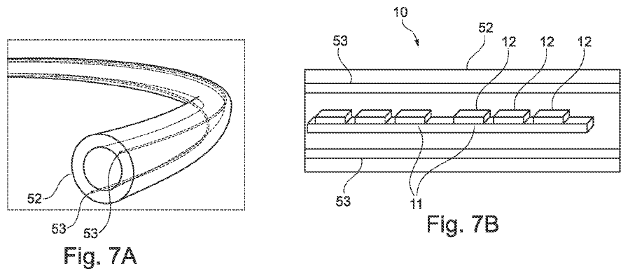

FIGS. 7A and 7B show illustrations of an example of an optoelectronic fiber 10.

The sheath 14 consists of a hose or tube 52, shown in perspective in FIG. 7A, with two collinear electrical lines 53 embedded in the hose wall. A different number of electrical lines 53 is also conceivable. As shown in the sectional view of FIG. 7B, the hose 52 contains the carriers 11 with the optoelectronic components 12.

The electrical lines 53 can be electrically coupled with the optoelectronic components 12 and/or external components. This makes it possible to interconnect the optoelectronic components 12 with each other or with a component outside the optoelectronic fiber 10.

1-22. (canceled)

23. An optoelectronic fiber comprising:
at least one carrier extending in a longitudinal direction;
optoelectronic components arranged on the at least one carrier; and
a sheath extending in the longitudinal direction and surrounding the at least one carrier and the optoelectronic components,
wherein the sheath comprises at least one thread guided around the at least one carrier and the optoelectronic components and/or at least one tape helically wound around the at least one carrier and the optoelectronic components,
wherein at least one metal wire is integrated into the sheath and twisted, braided or interwoven with the at least one thread, and
wherein the at least one metal wire is electrically coupled to at least one of the optoelectronic components.

24. The optoelectronic fiber according to claim 23, wherein the at least one thread comprises a plurality of threads which are twisted, braided or interwoven with each other.

25. The optoelectronic fiber according to claim 23, wherein the at least one carrier is formed by an extruded plastic carrier in which the optoelectronic components are embedded.

26. The optoelectronic fiber according to claim 23, wherein the at least one thread and/or the at least one tape are transparent or diffuse and/or contain a phosphor mixture and/or a conversion material.

27. A textile comprising:
a plurality of textile threads; and
the at least one optoelectronic fiber according to claim 23.

28. A moulded part comprising:
the at least one optoelectronic fiber according to claim 23.

29. A device comprising:
an assembly; and
the at least one optoelectronic fiber according to claim 23, which is firmly connected to the assembly.

30. An optoelectronic fiber comprising:
at least one carrier extending in a longitudinal direction and wound within itself;
optoelectronic components arranged on the at least one carrier; and
a sheath extending in the longitudinal direction and surrounding the at least one carrier and the optoelectronic components,
wherein the sheath is a hose, and
wherein at least one electrical line is integrated in a wall of the hose.

31. The optoelectronic fiber according to claim 30, wherein the at least one electrical line is electrically coupled to at least one of the optoelectronic components.

32. An apparatus for manufacturing an optoelectronic fiber, the apparatus comprising:
a feeding device configured to feed at least one carrier which extends in a longitudinal direction and on which optoelectronic components are arranged; and
a wrapping device configured to surround the at least one carrier and the optoelectronic components with a sheath extending in the longitudinal direction,
wherein the wrapping device is configured to guide at least one thread around the at least one carrier and the optoelectronic components and/or to helically wind at least one tape around the at least one carrier and the optoelectronic components.

33. The apparatus according to claim 32, wherein the wrapping device is configured to integrate at least one metal wire into the sheath, which is twisted, braided or interwoven with the at least one thread, and wherein the at least one metal wire is electrically coupled to at least one of the optoelectronic components.

34. The apparatus according to claim 32, wherein the wrapping device comprises a cross-linking device which is configured to cross-links together a plurality of threads guided around the at least one carrier and the optoelectronic components and/or the tape loops of the at least one tape wound helically around the at least one carrier and the optoelectronic components by melting or solidifying.

35. The apparatus according to claim 32,
wherein the wrapping device comprises a rotatably mounted twisting device having a first recess and a plurality of second recesses,
wherein the feeding device is configured to guide the at least one carrier with the optoelectronic components arranged thereon, coming from a first side of the twisting device, through the first recess,
wherein the threads coming from the first side of the twisting device are each guided through one of the second recesses, and
wherein the twisting device is configured to rotate such that the threads are guided around the at least one carrier and the optoelectronic components on a second side of the twisting device facing away from the first side.

36. The apparatus according to claim 35, wherein the first recess is arranged in an axis of rotation of the twisting device.

37. The apparatus according to claim 32, further comprising at least one bobbin from which the at least one thread is unwound.

38. A method for manufacturing an optoelectronic fiber, the method comprising:
providing at least one carrier extending in a longitudinal direction;
arranging optoelectronic components on the at least one carrier; and
surrounding the at least one carrier and the optoelectronic components with a sheath extending in the longitudinal direction,
wherein at least one thread is guided around the at least one carrier and the optoelectronic components for manufacturing the sheath and/or at least one tape is wound helically around the at least one carrier and the optoelectronic components for manufacturing the sheath.

39. The method according to claim 38, wherein at least one metal wire is integrated into the sheath and the at least one metal wire is twisted, braided or interwoven with the at least one thread, and wherein the at least one metal wire is electrically coupled to at least one of the optoelectronic components.

40. The method according to claim 38, wherein the at least one thread comprises a plurality of threads which are twisted, interlaced or woven together.

41. The method according to claim 38, wherein the threads guided around the at least one carrier and the optoelectronic components and/or a tape loops of the at least one tape wound helically around the at least one carrier and the optoelectronic components are cross-linked with one another by melting or solidification.

42. The method according to claim 38, wherein an extruded plastic carrier is produced which forms the carrier, and wherein the optoelectronic components are embedded in the extruded plastic carrier.

43. The method according to claim 38, further comprising:
providing a rotatably mounted twisting device with a first recess and several second recesses,
guiding the at least one carrier with the optoelectronic components arranged thereon through the first recess coming from a first side of the twisting device;
guiding the threads coming from the first side of the twisting device through one of the second recesses; and
rotating the twisting device such that the threads are guided around the at least one carrier and the optoelectronic components on a second side of the twisting device facing away from the first side.
